(19) United States
(12) Patent Application Publication
(10) Pub. No.: US 2014/0218863 A1
(43) Pub. Date: Aug. 7, 2014

(54) OUTDOOR DISPLAY DEVICE

(71) Applicant: Panasonic Corporation, Osaka (JP)

(72) Inventors: Tomonori YOSHIDA, Osaka (JP); Taichi Kishimoto, Osaka (JP)

(73) Assignee: Panasonic Corporation, Osaka (JP)

(21) Appl. No.: 14/170,649

(22) Filed: Feb. 3, 2014

(30) Foreign Application Priority Data
Feb. 6, 2013 (JP) 2013-021092
Dec. 10, 2013 (JP) 2013-254664

(51) Int. Cl. H05K 7/20

(52) U.S. Cl. CPC H05K 7/20145
USPC 361/692

(57) ABSTRACT

A display device comprises a display panel, a protective glass sheet disposed on the front face side of the display panel, a housing that holds the display panel, an exhaust fan that generates an air flow in the space between the display panel and the protective glass, an intake opening that draws air to be sent into the space in from the outside of the housing, an exhaust opening that exhausts air that has passed through the space to the outside of the housing, an ambient temperature sensor that senses the ambient temperature and the temperature of the intake opening, an exhaust-side temperature sensor that senses the temperature of the exhaust opening, and a controller that calculates the difference between the temperature sensed by the intake-side temperature sensor and the temperature sensed by the exhaust-side temperature sensor as a difference value, and determines the rotational speed of the exhaust fan on the basis of the ambient temperature and the difference value.

### CROSS-REFERENCE TO RELATED APPLICATIONS

This application claims priority to Japanese Patent Applications No. 2013-021092 filed on Feb. 6, 2013 and No. 2013-254664 on Dec. 10, 2013. The entire disclosure of Japanese Patent Application No. 2013-021092 and No. 2013-254664 are hereby incorporated herein by reference.

### BACKGROUND

1. Technical Field

The present disclosure relates to a liquid crystal display or another such display device, and more particularly relates to a display device that is installed outdoors, etc., and is equipped with a cooling function.

2. Description of the Related Art

Display devices that are used outdoors as advertising media, such as digital signage, have become very popular in recent years.

These display devices that are used outdoors are subjected to direct sunlight, so a problem has been that the temperature of the device tends to rise.

In view of this, Patent Literature 1 (Japanese Laid-Open Patent Application 2010-282109), for example, discloses a display device in which the temperature inside a device is sensed by a temperature sensor, and an illuminance sensor detects whether or not the device is in direct sunlight, so if the interior of the device becomes hot, or if the device is in direct sunlight, the display is halted, or a cooling fan is switched on.

Usually, an illuminance sensor is disposed somewhere near the front face of the display panel, but shadows thrown by nearby buildings may create a situation in which the majority of the display panel is in sunlight, but the sunlight does not hit the illuminance sensor.

If this happens, then even though the sun is shining on the display panel, the device will incorrectly conclude that the sun is not hitting it. As a result, the cooling fan will not be driven even though the device is in sunlight, which can lead to the problem of elevated temperature of the display panel.

Furthermore, even though the configuration disclosed in the above publication involves an illuminance sensor, which is more expensive than a temperature sensor, there is the risk that the illuminance sensor will react not only to sunlight, but also to light from street lights and so forth. Therefore, it is difficult to say that this configuration affords accurate detection that the temperature of a display panel surface has been elevated by sunlight.

With a display device that is used outdoors it is particularly important to avoid elevated temperature of a display panel surface that is in sunlight, but if a temperature sensor or the like is mounted directly to the surface of the display panel, it may interfere with the display.

Thus, it is important for an elevation in temperature at the surface of a display panel to be correctly detected, without the display on the display panel being blocked, and for the cooling fan to be driven on the basis of this detection result.

It is an object of the present disclosure to provide an outdoor display device with which cooling of a display device disposed outdoors can be properly carried out.

### SUMMARY

The outdoor display device disclosed herein comprises a display panel, a transparent protective member, a housing, a fan, a driver, an intake component, an exhaust component, a first temperature sensor, a second temperature sensor, and a controller. The transparent protective member is provided, with a specific gap in between, on the front face side of the display panel. The housing holds the display panel. The fan generates an air flow in the specific gap formed between the display panel and the protective member. The driver rotationally drives the fan. The intake component draws air to be sent into the gap in from the outside of the housing. The exhaust component exhausts air that has passed through the gap to the outside of the housing. The first temperature sensor senses the ambient temperature and the temperature on the intake component side. The second temperature sensor senses the temperature on the exhaust component side. The controller calculates the difference between the temperature on the intake side sensed by the first temperature sensor and the temperature on the exhaust side sensed by the second temperature sensor as a difference value, and controls the driver to set a rotational speed on the basis of the difference value and the ambient temperature sensed by the first temperature sensor.

With the present disclosure disclosed herein, cooling of the display panel of a display device that is used outdoors can be carried out better.

### BRIEF DESCRIPTION OF THE DRAWINGS

FIG. 1 is a simplified lateral cross section of the display device pertaining to an embodiment of the present disclosure.

FIG. 2 is a simplified view of the display device, as seen from the rear.

FIG. 3 is a control block diagram of the display device.

FIG. 4 is a diagram of the functional blocks formed inside the display device.

FIG. 5 is a flowchart of an example of control executed by the display device.

FIG. 6 is a graph of the staged control of fan rotation in the display device.

### DETAILED DESCRIPTION

The display device pertaining to an embodiment of the present disclosure will now be described through reference to the drawings.

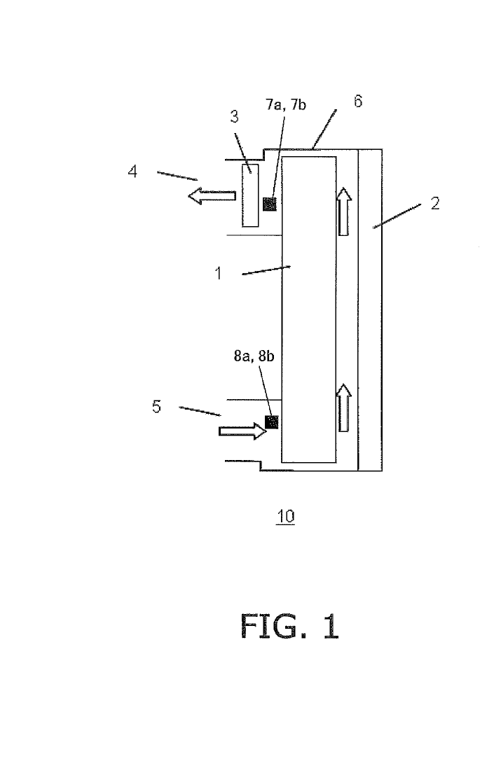

FIG. 1 is a simplified view of a cross section of a display device 10 as seen from the side. The display device 10 is mainly used in digital signage that is used outdoors, and comprises a display panel 1, a protective glass sheet 2 (an example of a protective member), an exhaust fan 3 (an example of a fan), an exhaust opening 4 (an example of an exhaust component), an intake opening 5 (an example of an intake component), and a housing 6.

The display panel 1 is a liquid crystal display panel, and displays video and the like related to various kinds of advertising.

In this embodiment, a liquid crystal display panel is used as the display device, but a plasma panel or an organic EL panel can also be used.

The protective glass sheet 2 is disposed on the front face side of the display panel 1, at a position that is separated by a specific gap away from the display panel 1. Consequently, the protective glass sheet 2 protects the display panel 1 against impact, water, dust, and so on.

The exhaust fan 3 is rotationally driven by a drive motor 3a (an example of a driver), and is provided to prevent heat from being generated at the front face of the display panel 1 when an air flow is forced between the display panel 1 and the protective glass sheet 2. The exhaust fan 3 is provided on the upper side in the space on the rear face side of the display panel 1.

The exhaust opening 4 is disposed the farthest downstream in the flow of air produced by the rotation of the exhaust fan 3, and exhausts air to the outside of the housing 6.

The intake opening 5 is disposed the farthest upstream in the flow of air produced by the rotation of the exhaust fan 3, and draws air into the housing 6. More specifically, the intake opening 5 is provided at a position on the lower side on the rear face side of the display panel 1.

Thus, with the configuration of the display device 10 in this embodiment, outside air is taken in from the lower side of the rear face of the display panel 1, and the air thus taken in flows from bottom to top over the front face of the display panel 1, and is exhausted from the intake opening 5 via the exhaust fan 3 disposed on the upper side of the rear face.

Further, in this embodiment no fan is provided on the intake side, and air intake is performed only by the exhaust fan 3 on the exhaust side, but air intake may instead be performed only by an intake fan on the intake side, or fans may be provided both on the intake side and on the exhaust side.

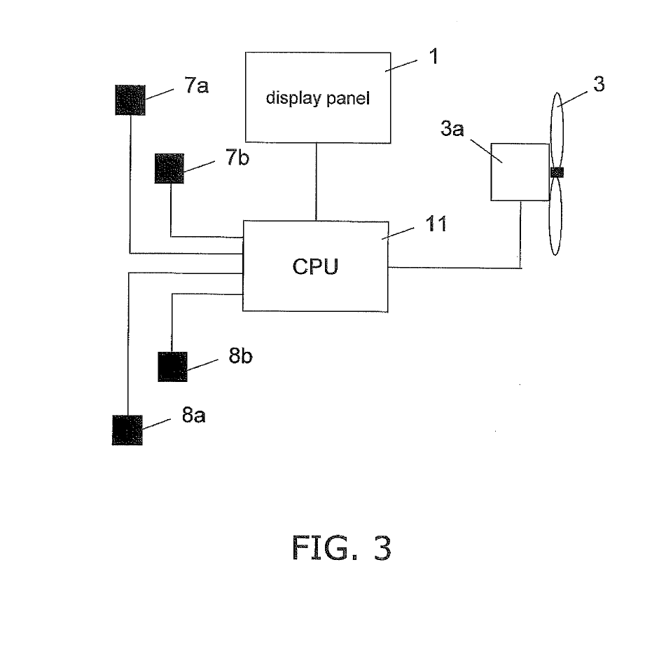

The housing 6 is a box-shaped member made of metal or plastic, and holds in its interior the display panel 1 and electrical circuits and so forth including a CPU 11 (see FIG. 3) for driving the display panel 1.

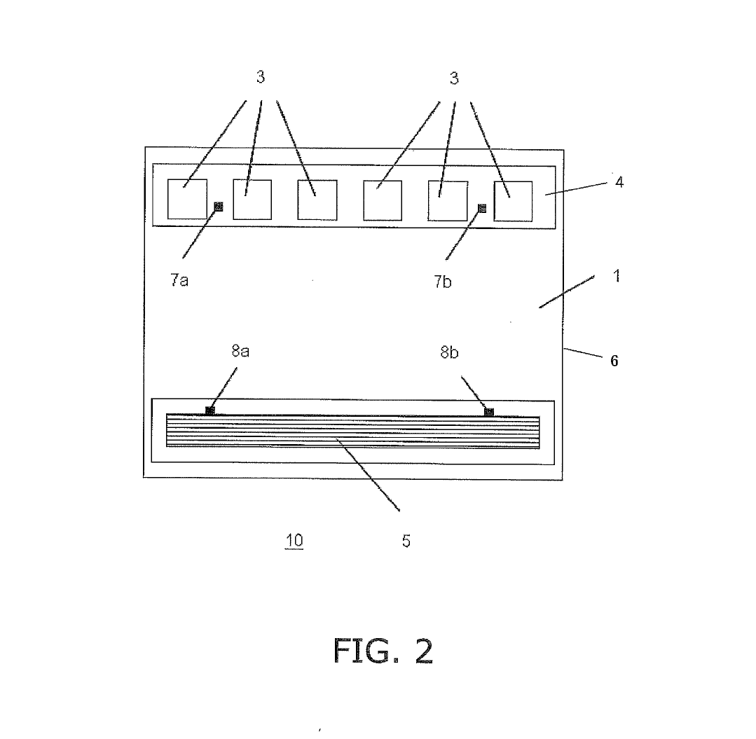

FIG. 2 is a simplified view of the display device 10 as seen from the rear.

As shown in FIG. 2, with the display device 10 in this embodiment, six exhaust fans 3 are disposed horizontally at the height position where the exhaust opening 4 is formed. That is, the exhaust fans 3 and the exhaust opening 4 are disposed at positions where they overlap in a plan view perpendicular to the display panel 1.

Consequently, the flow of air formed by the exhaust fans 3 can carry the heat generated in the space inside the housing 6 to the outside of the housing 6 through the exhaust opening 4.

Also, as shown in FIGS. 1 and 2, exhaust-side temperature sensors 7a and 7b are disposed near the exhaust fans 3, at positions along the path of the air flow formed by the exhaust fans 3 on the rear face side of the display panel 1. The exhaust-side temperature sensors 7a and 7b measure the temperature of air discharged to the outside of the housing 6.

As shown in FIGS. 1 and 2, meanwhile, intake-side temperature sensors 8a and 8b are disposed near the intake opening 5, at positions along the path of the air flow formed by the exhaust fans 3 on the rear face side of the display panel 1. The intake-side temperature sensors 8a and 8b measure the temperature of air flowing from the outside of the housing 6 into the interior of the housing 6.

A dust filter that prevents infiltration by dust, and a baffle that prevents infiltration by water are provided to the intake opening 5. Similarly, a dust filter and baffle are also provided to the exhaust opening 4.

In this embodiment, the baffle and dust filter on the exhaust opening 4 side are provided on the rear face side (the protective glass sheet 2 side) of the exhaust fans 3.

With the display device 10 in this embodiment, the ambient temperature T1 is also taken into account in determining the rotational speed of the exhaust fans 3 (discussed below). The temperature of the intake air measured by the intake-side temperature sensors 8 is measured right after the air is taken into the housing 6, so it is substantially the same as the outside air temperature. Thus, with the display device 10 in this embodiment, the processing discussed below is performed by assuming that the temperature measured by the intake-side temperature sensors 8 is the ambient temperature.

FIG. 3 is a diagram of the control blocks formed within the display device 10 in this embodiment.

As shown in FIG. 3, the display device 10 in this embodiment is such that the CPU 11 is connected to the display panel 1, the exhaust-side temperature sensors 7a and 7b, the intake-side temperature sensors 8a and 8b, and the drive motors 3a of the exhaust fans 3.

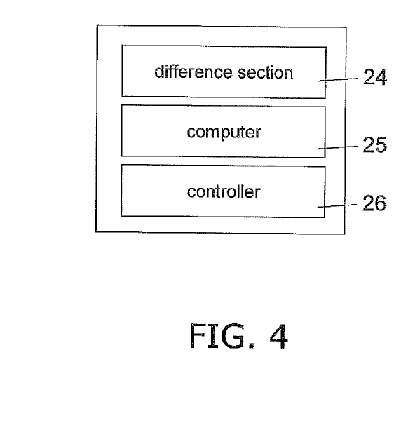

The CPU 11 reads various programs stored in a memory component or the like (not shown), forms the functional blocks shown in FIG. 4 (a difference section (controller) 24, a computer (controller) 25, and a controller (controller) 26), and executes rotational speed control over the exhaust fans 3 (discussed below).

The difference section 24 calculates the difference between the intake temperature T22 sensed by the intake-side temperature sensor 8a, 8b and the exhaust temperature T21 sensed by the exhaust-side temperature sensor 7a, 7b.

The computer 25 calculates a temperature control factor F found from the following equation (1).

F=T1+α×T2 (1)

α here is a coefficient.

The value of the coefficient α is set by taking into account a number of parameters, such as the cooling capacity of the fans (the fan speed, etc.) and the amount of sunlight on the display device 10. With the display device 10 in this embodiment, α is set to a value greater than 1.0 in order to control the speed of the exhaust fans 3 so that the effect of the difference value T2 indicating the temperature difference between the exhaust temperature T21 and the intake temperature T22 will be greater than the effect of the ambient temperature T1.

The controller 26 sets the speed of the exhaust fans 3 on the basis of the result of contrasting the temperature control factor F calculated by the computer 25 with specific thresholds (a first specific threshold th1 and a second specific threshold th2).

The specific control of the speed of the exhaust fans 3 will be described in the course of the control flow discussed below.

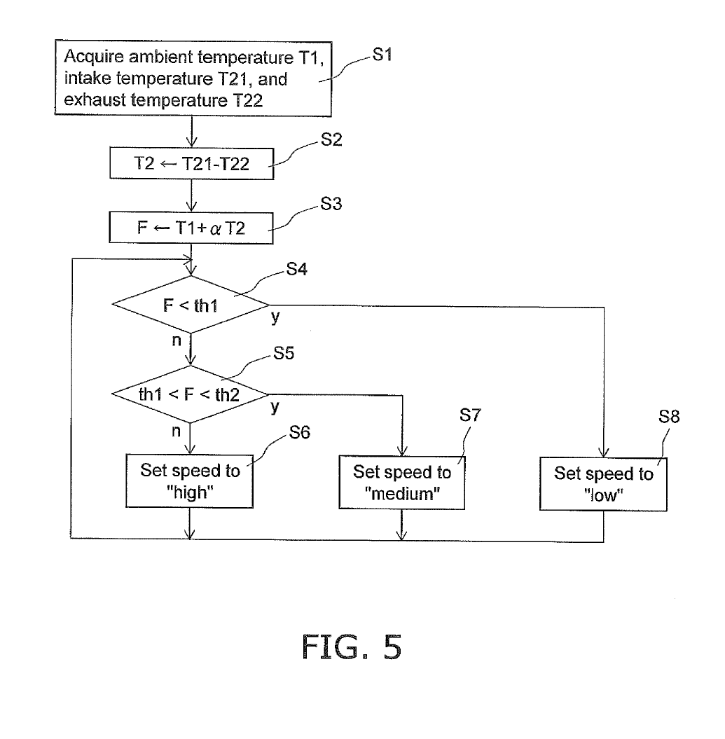

FIG. 5 is a flowchart of an example of control executed by the display device 10. The following control is executed by the CPU 11, etc., mounted inside the housing 6 of the display device 10.

First, in step S1, the ambient temperature T1 measured by the intake-side temperature sensors 8, which are also used as ambient temperature sensors, are acquired. Also, the exhaust temperature T21 measured by the exhaust-side temperature sensors 7 and the intake temperature T22 measured by the intake-side temperature sensors 8 are acquired.

In step S2, the difference value T2 between the exhaust temperature T21 and the intake temperature T22 acquired above is calculated.

In step S3, the temperature control factor F is calculated from the above-mentioned Equation 1.

In step S4, it is determined whether or not the temperature control factor F is less than the first specific threshold th1. If the temperature control factor F is less than the first specific threshold th1, the speed of the exhaust fans 3 is set to “low” (step S5).

On the other hand, if the temperature control factor F is greater than the first specific threshold th1, the flow proceeds to step S6.

In step S6, it is determined whether or not the temperature control factor F is within a range between the first specific threshold th1 and the second specific threshold th2. If the temperature control factor F is between (within the range of) the above-mentioned first and second specific thresholds th1 and th2, the speed of the exhaust fans 3 is set to “medium” (step S7).

On the other hand, if the temperature control factor F is not within this range (that is, if it is greater than the second specific threshold th2), the speed of the exhaust fans 3 is set to “high” (step S8).

After the completion of step S5, S7, or S8, the flow returns to step S4.

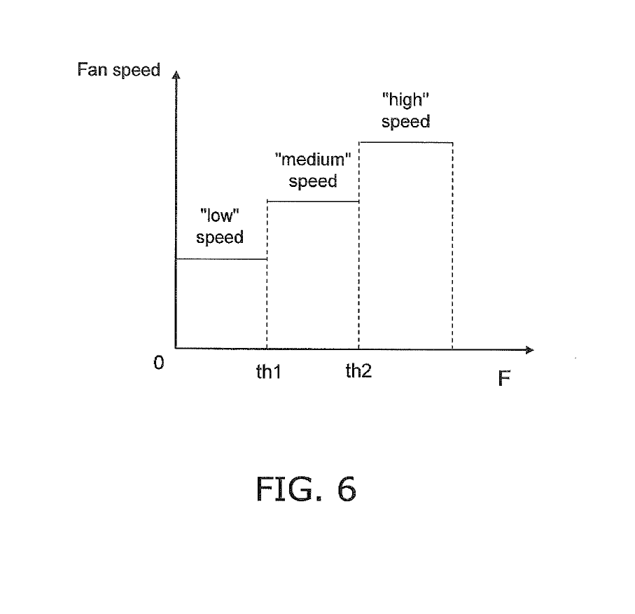

Specifically, with the display device 10 in this embodiment, as discussed above, the temperature control factor F is compared with the first and second specific thresholds th1 and th2, and the speed of the exhaust fans 3 is controlled in three stages as shown in FIG. 6.

More specifically, if the value of the temperature control factor F is less than the first specific threshold th1, the speed of the exhaust fans 3 is set to “low.” If the temperature control factor F is between the first and second specific thresholds th1 and th2, the speed of the exhaust fans 3 is set to “medium.” If the temperature control factor F is greater than the second specific threshold th2, the speed of the exhaust fans 3 is set to “high.”

In this embodiment, since the display device 10 is installed outdoors where it is subjected to direct sunlight, the exhaust fans 3 are operated as discussed above to pass air through the gap between the protective glass sheet 2 and the front face of the display panel 1.

If the fans are merely operated at their highest speed at this point, this will result in more noise and the power consumption will also rise.

If, for example, there is a large amount of sunlight, then even though the outside temperature may be low, there is the risk that the surface temperature of the display panel 1 will increase. Also, even though there may be little sunlight, if the outside temperature is high, there is again the risk that the surface temperature of the display panel 1 will increase.

In view of this, with the display device 10 in this embodiment, the speed of the exhaust fans 3 is controlled on the basis of the sum (the temperature control factor F) of the factor (T1) related to outside temperature and the factor (α×T2) related to the amount of sunlight.

More specifically, with the display device 10 in this embodiment, we focus on the fact that if the amount of sunlight is constant, the temperature difference between the temperature of air going to the front face of the display panel 1 and the temperature of the air coming out (which is a function of the fan speed), will be substantially constant, and the factor related to sunlight is determined on the basis of the temperature difference between intake and exhaust air (the difference value T2=the exhaust temperature T21−the intake temperature T22).

In contrast, with a conventional method in which an illuminance sensor is used to estimate the amount of sunlight, there is the risk that the surface temperature of the liquid display panel will not match the estimated temperature of the display panel based on the result found by the illuminance sensor, so the proper control cannot be carried out.

With the display device 10 in this embodiment, the above-mentioned problems can be solved, and better panel cooling control can be executed, by employing the control method discussed above.

Also, with the display device 10 in this embodiment, as shown in FIG. 2, the exhaust fans 3, the exhaust opening 4 and the intake opening 5 are disposed along the long side of the display device 10 in a front view.

Consequently, the cooling of the display panel 1 can be performed effectively by the air trapped by the exhaust fan 3 since the distance from the intake opening 5 to the exhaust opening 4 is long.

Also, the intake opening 5 is apart from the exhaust fan 3 just at a distance of the short side of the display device 10 in a front view.

Therefore, as compared with the structure in which the intake opening and the exhaust fan are disposed along the long side of the display device in a front view, the cooling of the display panel can be performed effectively by making good use of suction power by the exhaust fan 3.

### Other Embodiments

An embodiment of the present disclosure was described above, but the present disclosure is not limited to or by the above embodiment, and various modifications are possible without departing from the gist of the disclosure.

(A)

In the above embodiment, an example was given in which the intake-side temperature sensors 8a and 8b provided near the intake opening 5 were used as the first temperature sensor for sensing the ambient temperature outside the housing 6 and the second temperature sensor for measuring the temperature of the intake air, but the present disclosure is not limited to this.

For example, a dedicated ambient temperature sensor may be separately provided for measuring the ambient temperature.

As discussed above, however, the intake temperature sensed by the intake-side temperature sensor is measured right after the air comes into the housing, so it should not be much different from the ambient temperature. Thus, even when employing a configuration in which the ambient temperature and the intake temperature are sensed by a single temperature sensor, as in this embodiment, the same effect can be obtained as that obtained with this technology, and the number of parts can also be reduced.

(B)

In the above embodiment, an example was given in which drive was performed using six fans, but the present disclosure is not limited to this.

For example, it is conceivable that only four of the six fans can be used because of the relation to the total power supply capacity of the display device. In this case, four fans are driven by a dedicated power supply, and the remaining two fans may share their power supply with that of the backlight (CCFL light source) of the display panel.

A characteristic of using a CCFL light source as the backlight of the display panel is that the current value of the backlight decreases as the temperature rises. Thus, this characteristic can be taken advantage of to raise the output of the backlight, and the surplus power can be used to drive the remaining two fans.

Furthermore, when a configuration such as the above is employed, cooling inside the display device 10 is usually performed with fewer fans. Therefore, to obtain a given cooling effect, the four fans have to be rotated faster than when six fans are used. Thus, when four fans are used, it is preferable to set the value of the coefficient α higher than when six fans are used. This allows fan speed control to be performed so that increasing or decreasing the difference value T2 in the above-mentioned Equation 1 (the temperature difference between intake and exhaust) will have a greater effect.

(C)

In the above embodiment, an example was given in which the display device 10 was used in a so-called horizontal installation (in which the length of the display screen in the horizontal direction is greater than the length in the vertical direction), but the present disclosure is not limited to this.

For example, the display device 10 may instead be installed vertically (so that the length of the display screen in the vertical direction is greater than the length in the horizontal direction).

In this case, the exhaust opening 4 is disposed not on the upper side of the rear face of the display panel 1, but on the side (the right side when seen from the front, for example).

How heat is conducted is different with a vertical installation and with a horizontal installation, so control is preferably performed differently from when the installation is horizontal. For example, the value of the above-mentioned coefficient α may be different when the installation is horizontal and vertical.

Also, when the display device is installed vertically, the temperature tends to be higher at the upper part of the display device 10 because of the tendency of heat to rise. Thus, the exhaust fans 3 on the upper side may be operated at a higher speed than the exhaust fans 3 on the lower side, so that cooling is improved on the upper side of the display device 10.

Also, when the display device is installed vertically, since warmed air moves upward, this creates a difference between the temperatures on the upper and lower sides in the space inside the housing. Thus, if the display device 10 shown in FIG. 2 is installed vertically so that the right side is on top, for example, then of the four temperature sensors shown in FIGS. 1 and 2 (the exhaust-side temperature sensors 7a and 7b and the intake-side temperature sensors 8a and 8b), the temperature difference between the exhaust-side temperature sensor 7a and the intake-side temperature sensor 8a disposed on the lower side is calculated, the temperature difference between the exhaust-side temperature sensor 7b and the intake-side temperature sensor 8b disposed on the upper side is calculated, and the cooling fans may be controlled the greater of the two temperature differences as a reference.

Consequently, safer control can be accomplished by calculating the temperature differences between the upper and lower spaces when the display device 10 is installed vertically, and controlling the drive of the cooling fans by using the greater temperature difference as a reference.

### GENERAL INTERPRETATION OF TERMS

In understanding the scope of the present invention, the term “configured” as used herein to describe a component, section, or part of a device includes hardware and/or software that is constructed and/or programmed to carry out the desired function.

In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applies to words having similar meanings such as the terms “including,” “having,” and their derivatives. Also, the terms “part,” “section,” “portion,” “member,” or “element” when used in the singular can have the dual meaning of a single part or a plurality of parts.

Terms that are expressed as “means-plus function” in the claims should include any structure that can be utilized to carry out the function of that part of the present invention. Finally, terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

What is claimed is:

1. An outdoor display device, comprising:
a display panel;
a transparent protective member provided on a front face side of the display panel;
a specific gap in between the transparent protective member and the display panel;
a housing configured to hold the display panel;
a fan configured to generate an air flow in the specific gap;
a driver configured to rotationally drive the fan;
an intake component configured to draw air from outside of the housing, the air drawn into the specific gap;
an exhaust component configured to exhaust air outside of the housing, the air having flowed through the specific gap;
a first temperature sensor configured to sense an ambient temperature and an intake temperature of air outside of the intake component;
a second temperature sensor configured to sense an exhaust temperature of air exiting the exhaust component; and
a controller configured to calculate a difference value based on the difference in temperature between the intake temperature and the exhaust temperature, and control the driver to set a rotational speed based on the difference temperature and the ambient temperature.

2. The display device according to claim 1, wherein:
the controller increases rotational speed of the fan as the difference value increases.

3. The display device according to claim 1, wherein:
the controller controls the rotational speed of the fan to vary in a plurality of stages, the stages corresponding to a magnitude of the difference value.

4. The display device according to claim 1, wherein:
the first temperature sensor includes an ambient sensor configured to sense the ambient temperature, and an intake-side temperature sensor configured to sense the intake temperature.

5. The display device according to claim 1, wherein:
the controller controls the drive of the fan such that the difference value is greater than the ambient temperature.

6. The display device according to claim 1, wherein:
the fan is disposed nearer to the intake component than to exhaust component.

7. The display device according to claim 1, wherein:
the fan is disposed nearer to the exhaust component than to intake component.

8. The display device according to claim 1, wherein:
the intake component further includes a dust filter configured to prevent infiltration by dust, and a baffle configured to prevent infiltration by water.

9. The display device according to claim 1, wherein:
the exhaust component further includes a dust filter configured to prevent infiltration by dust, and a baffle configured to prevent infiltration by water.

10. The display device according to claim 1, wherein:
the controller calculates a control factor according to the equation
F=T1+α×T2
wherein F is the control factor, T1 is the ambient temperature, α is a coefficient, and T2 is the difference value.

11. The display device according to claim 10, wherein:
α is determined by a plurality of parameters, the parameters including cooling capacity of the fan, and an amount of sunlight on the display device.

12. The display device according to claim 10, further including:
a plurality of fans;
wherein α is determined by a plurality of parameters, the parameters including cooling capacity of the fans, and an amount of sunlight on the display device.

13. The display device according to claim 12, wherein:
which fans, of the plurality of fans, that are used to cool the display device is based upon the control factor.

14. The display device according to claim 12, wherein:
a number of the plurality of fans that are used to cool the display device is dependent upon the control factor.

15. The display device according to claim 1, wherein:
the exhaust component is further configured to draw air from outside of the housing, the air drawn into the specific gap;
the intake component is further configured to exhaust air outside of the housing, the air having flowed through the specific gap; and
the controller is further configured to control a direction of air flow between the exhaust component and the intake component.
